(19) United States
(12) Patent Application Publication
(10) Pub. No.: US 2026/0344263 A1
(43) Pub. Date: Oct. 29, 2026

(54) DISPLAY SUBSTRATE, MANUFACTURING METHOD, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Pan XU, Beijing (CN); Xing ZHANG, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/839,646

(22) PCT Filed: Dec. 12, 2023
(86) PCT No.: PCT/CN2023/138025

§ 371 Date: Aug. 19, 2024

(51) Int. Cl. H10K 59/80; H10K 59/12; H10K 59/122; H10K 59/35

(52) U.S. Cl. CPC H10K 59/879; H10K 59/1201; H10K 59/122; H10K 59/351

(57) ABSTRACT

A display substrate, a manufacturing method and a display apparatus. The display substrate includes a base substrate, and a plurality of sub-pixels arranged on the base substrate and including pixel aperture regions. The display substrate further includes a plurality of lens units, at least a part of each lens unit is arranged in a corresponding pixel aperture region, each lens unit includes a plurality of lenses arranged in an array form, each lens includes a central lens portion and at least one peripheral lens portion, and the peripheral lens portion surrounds the central lens portion.

### TECHNICAL FIELD

The present disclosure relates to the field of display technology, in particular to a display substrate, a manufacturing method, and a display apparatus.

### BACKGROUND

Along with the development of the display technology, display products have been applied more and more widely, and the types of display products become more and more. In large-size Organic Light-Emitting Diode (OLED) display products, bottom-emission OLED architecture is mature and simple, so it is currently widely used in a large-size WOLED product. However, a pixel circuitry occupies a large space in the display product, so an aperture ratio of the display product is small. Hence, there is an urgent need to improve the luminous efficiency of the display product.

### SUMMARY

An object of the present disclosure is to provide a display substrate, a manufacturing method, and a display apparatus, so as to solve problems in the related art.

In order to achieve the above-mentioned object, the present disclosure provides the following technical solutions.

In one aspect, the present disclosure provides in some embodiments a display substrate, including a base substrate, and a plurality of sub-pixels arranged on the base substrate and including pixel aperture regions. The display substrate further includes a plurality of lens units, at least a part of each lens unit is arranged in a corresponding pixel aperture region, each lens unit includes a plurality of lenses arranged in an array form, each lens includes a central lens portion and at least one peripheral lens portion, and the peripheral lens portion surrounds the central lens portion.

In a possible embodiment of the present disclosure, an orthogonal projection of the central lens portion onto the base substrate has a first boundary, and an orthogonal projection of the peripheral lens portion onto the base substrate has an outer boundary arranged away from the central lens portion and having a same shape as the first boundary.

In a possible embodiment of the present disclosure, a difference d1 between a width of the central lens portion and a width of the peripheral lens portion along an extension direction of an axis of symmetry of the central lens portion is less than or equal to 0.3 μm.

In a possible embodiment of the present disclosure, the central lens portion includes a first edge portion, and an orthogonal projection of the first edge portion onto the base substrate forms the first boundary; the peripheral lens portion includes an outer edge portion, and an orthogonal projection of the outer edge portion onto the base substrate forms the outer boundary; and a difference h1 between a height of the first edge portion and a height of the outer edge portion in a direction perpendicular to the base substrate is less than or equal to 0.3 μm.

In a possible embodiment of the present disclosure, the central lens portion includes a first edge portion, and an orthogonal projection of the first edge portion onto the base substrate forms the first boundary; the peripheral lens portion includes an outer edge portion, and an orthogonal projection of the outer edge portion onto the base substrate forms the outer boundary; and a difference d2 between a width of the first edge portion and a width of the outer edge portion in a direction parallel to the base substrate is less than or equal to 0.3 μm.

In a possible embodiment of the present disclosure, a difference h2 between a maximum depth of the central lens portion and a maximum depth of the peripheral lens portion in the direction perpendicular to the base substrate is less than or equal to 0.3 μm.

In a possible embodiment of the present disclosure, the outer boundary is of a regular hexagonal shape.

In a possible embodiment of the present disclosure, the central lens portion includes a first edge portion, the first edge portion includes first edges and first corners arranged alternately, each first edge is coupled to an adjacent first corner, and a height of the first edge gradually decreases in a direction away from the first corner to which the first edge is coupled.

In a possible embodiment of the present disclosure, the peripheral lens portion includes an outer edge portion, the outer edge portion includes outer edges and outer corners arranged alternately, each outer edge is coupled to an adjacent outer corner, and a height of the outer edge decreases in a direction away from the outer corner to which the outer edge is coupled.

In a possible embodiment of the present disclosure, in the lens unit, a contact member is formed among three adjacent lenses, and the contact member is provided with a sharp portion at a surface away from the base substrate.

In a possible embodiment of the present disclosure, the display substrate further includes a pixel definition layer for defining the pixel aperture regions, and in at least a part of the lens units, orthogonal projections of a part of the lenses at a periphery of the pixel aperture region onto the base substrate at least partially overlap with an orthogonal projection of the pixel definition layer onto the base substrate.

In a possible embodiment of the present disclosure, the lens includes a first peripheral lens portion surrounding the central lens portion and a second peripheral lens portion surrounding the first peripheral lens portion.

In a possible embodiment of the present disclosure, the plurality of sub-pixels includes a first color sub-pixel and a second color sub-pixel, a driving current corresponding to the first color sub-pixel is greater than a driving current corresponding to the second color sub-pixel, and a filling rate of the lens unit in the pixel aperture region corresponding to the first color sub-pixel is greater than a filling rate of the lens unit in the pixel aperture region corresponding to the second color sub-pixel.

In a possible embodiment of the present disclosure, the plurality of sub-pixels includes a red sub-pixel, a green sub-pixel and a blue sub-pixel, a driving current corresponding to the red sub-pixel is greater than a driving current corresponding to the green sub-pixel, and a driving current corresponding to the green sub-pixel is greater than a driving current corresponding to the blue sub-pixel; a filling rate of the lens unit in the pixel aperture region corresponding to the red sub-pixel is greater than a filling rate of the lens unit in the pixel aperture region corresponding to the green sub-pixel; and a filling rate of the lens unit in the pixel aperture region corresponding to the green sub-pixel is greater than a filling rate of the lens unit in the pixel aperture region corresponding to the blue sub-pixel.

In a possible embodiment of the present disclosure, the plurality of sub-pixels further includes a white sub-pixel, a driving current corresponding to the white sub-pixel is less than the driving current corresponding to the blue sub-pixel, and a filling rate of the lens unit in the pixel aperture region corresponding to the white sub-pixel is less than the filling rate of the lens unit in the pixel aperture region corresponding to the blue sub-pixel.

In a possible embodiment of the present disclosure, the plurality of sub-pixels includes a red sub-pixel, a green sub-pixel, a blue sub-pixel and a white sub-pixel. A pixel aperture region of the white sub-pixel is not filled with the lens unit; or a pixel aperture region of at least one of the red sub-pixel, the green sub-pixel and the blue sub-pixel is not filled with the lens unit; or the pixel aperture region of the white sub-pixel is not filled with the lens unit, and the pixel aperture region of at least one of the red sub-pixel, the green sub-pixel and the blue sub-pixel is not filled with the lens unit.

In a possible embodiment of the present disclosure, the display substrate further includes a driving circuitry layer and a color film layer, the driving circuitry layer is arranged at a side of the color film layer facing the base substrate, the color film layer is arranged at a side of the lens unit facing the base substrate, and an orthogonal projection of the color film layer onto the base substrate at least partially overlaps with an orthogonal projection of the pixel aperture region onto the base substrate.

In another aspect, the present disclosure provides in some embodiments a display apparatus including the above-mentioned display substrate.

In yet another aspect, the present disclosure provides in some embodiments a method for manufacturing the above-mentioned display substrate, the display substrate including a base substrate and a plurality of sub-pixels arranged on the base substrate, the sub-pixel including a pixel aperture region, the display substrate further including a plurality of lens units, at least a part of each lens unit being arranged in a corresponding pixel aperture region, the method including forming the lens unit, wherein the forming the lens unit includes: forming an organic material layer on the base substrate; forming a photoresist layer at a side of the organic material layer away from the base substrate, and patterning the photoresist layer to form a photoresist pattern; and etching the organic material layer with the photoresist pattern as a mask to form the lens unit, the lens unit including a plurality of lenses arranged in an array form, and each lens including a central lens portion and at least one peripheral lens portion surrounding the central lens portion.

In a possible embodiment of the present disclosure, the etching the organic material layer with the photoresist pattern as a mask specifically includes, after the formation of the lens unit, forming a contact member among three adjacent lenses in the lens unit through etching, the contact member being provided with a sharp portion at a surface away from the base substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a planar view of a lens according to one embodiment of the present disclosure;

FIG. 2 is an electron micrograph of a lens unit according to one embodiment of the present disclosure;

FIG. 3 is an electron micrograph of the lens unit according to one embodiment of the present disclosure;

FIG. 4 is a planar view of the lens according to one embodiment of the present disclosure;

FIG. 5 is a schematic view showing the arrangement of the lens units for RGBW sub-pixels according to one embodiment of the present disclosure;

FIG. 6 is a planar view of the lens according to one embodiment of the present disclosure;

FIG. 7 is a sectional view of film layers of a sub-pixel according to one embodiment of the present disclosure;

FIG. 8 is a schematic view showing the arrangement of the lens units for the RGBW sub-pixels according to one embodiment of the present disclosure;

FIG. 9 is a sectional view of the sub-pixels along line A1A2 in FIG. 8;

FIG. 10 is a sectional view of a complete lens along line A3A4 in FIG. 8;

FIG. 11 is an electron micrograph of the lens unit according to one embodiment of the present disclosure;

FIG. 12 is an electron micrograph of the lens unit according to one embodiment of the present disclosure;

FIG. 13 is a schematic view showing the arrangement of the lens unit for RGBW sub-pixels according to one embodiment of the present disclosure;

FIG. 14 is a sectional view of the sub-pixels along line B1B2 in FIG. 13;

FIG. 15 is a schematic view showing the arrangement of the lens units for the RGBW sub-pixels according to one embodiment of the present disclosure;

FIG. 16 is a sectional view of the sub-pixels along line B5B6 in FIG. 15;

FIG. 17 is a schematic view showing the arrangement of the lens units for the RGBW sub-pixels according to one embodiment of the present disclosure; and

FIG. 18 is a sectional view of the sub-pixels along line B3B4 in FIG. 17.

### DETAILED DESCRIPTION

The present disclosure will be described hereinafter in conjunction with the drawings and embodiments.

In order to improve the luminous efficiency of a display product, a micro lens array (MLA) is used in the display product, i.e., micro-lenses are arranged in an array form in a pixel aperture region.

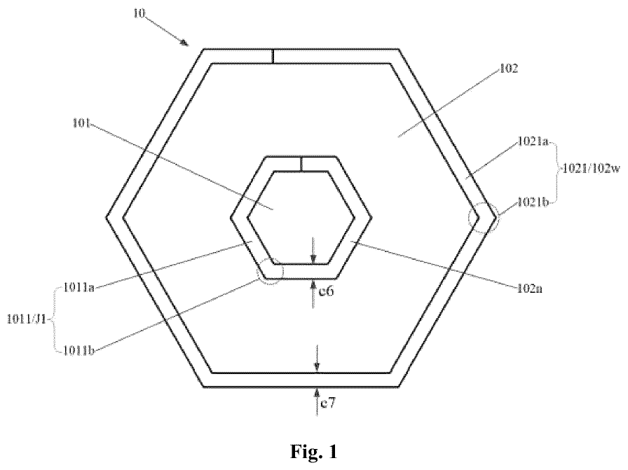

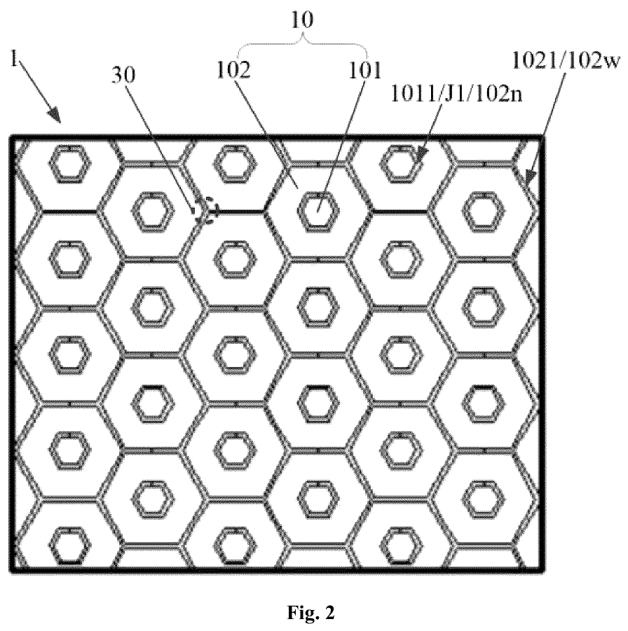

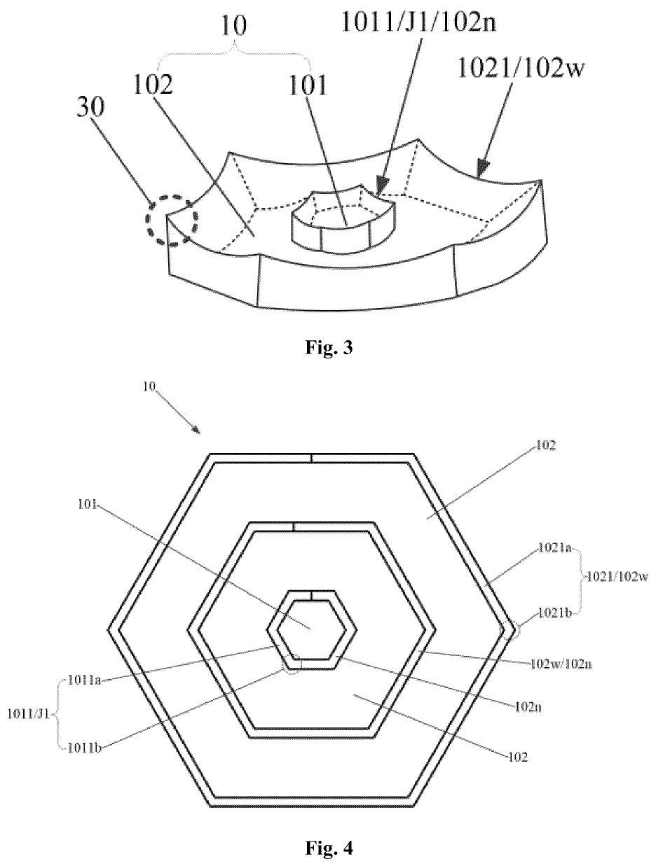

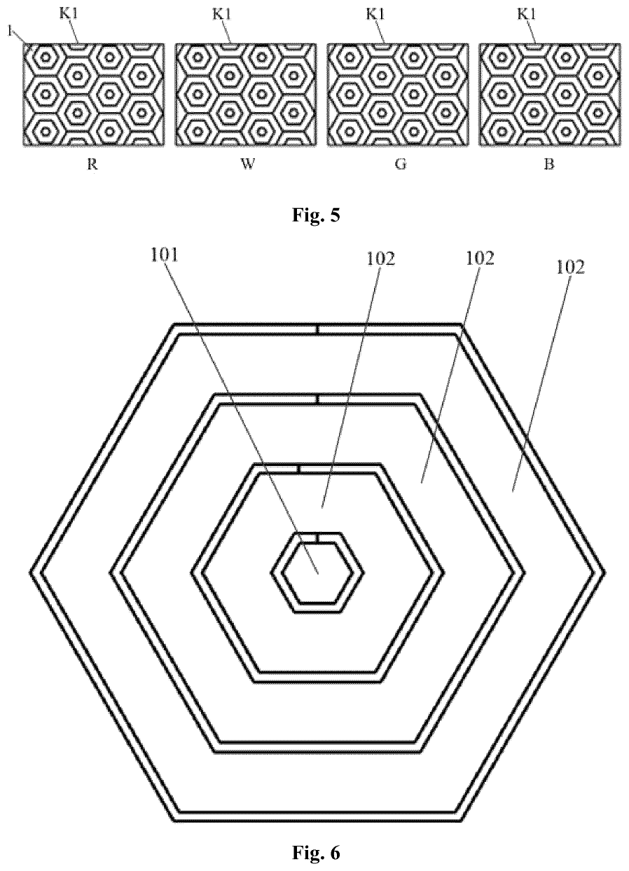

Referring to FIGS. 1 to 7, the present disclosure provides in some embodiments a display substrate, which includes a base substrate and a plurality of sub-pixels arranged on the base substrate and including pixel aperture regions K1. The display substrate further includes a plurality of lens units 1, and at least a part of the lens units 1 are arranged in a corresponding pixel aperture region K1. Each lens unit 1 includes a plurality of lenses 10 arranged in an array form, and each lens 10 includes a central lens portion 101 and at least one peripheral lens portion 102 surrounding the central lens portion 101.

Illustratively, the display substrate includes a plurality of sub-pixels, and a plurality of pixel aperture regions Klin the sub-pixels is arranged in an array form. Each sub-pixel includes a sub-pixel driving circuitry and a light-emitting element. The sub-pixel driving circuitry is coupled to an anode Ano of the light-emitting element, and configured to apply a driving signal to the light-emitting element so as to drive the light-emitting element to emit light. The light-emitting element further includes a light-emitting functional layer EL, and at least a part of the light-emitting functional layer EL and at least a part of the anode Ano are both arranged in the corresponding pixel aperture region K1.

Illustratively, the plurality of lens units 1 corresponds to the plurality of pixel aperture regions K1 respectively, at least a part of the lens unit 1 is arranged in the corresponding pixel aperture region K1.

Illustratively, the central lens portion 101 includes a recess, and a first edge portion 1011 coupled to the recess at a periphery of the recess.

Illustratively, the peripheral lens portion 102 includes a recess, an inner edge portion arranged at a side of the recess near the central lens portion 101, and an outer edge portion 1021 arranged at a side of the recess away from the central lens portion 101. For example, the first edge portion 1011 of the central lens portion 101 may be reused as the inner edge portion of the adjacent peripheral lens portion 102.

Illustratively, a resin layer Resin is patterned to form the plurality of lens units 1 directly, but the present disclosure is not limited thereto. It should be appreciated that, the resin layer, also referred to as a planarization layer, is, but not limited to, formed between the sub-pixel driving circuitry and the anode Ano.

Illustratively, the lens unit 1 is arranged between the anode Ano and the base substrate. In the pixel aperture region K1, both the anode Ano and the light-emitting functional layer EL are formed on the lens unit 1, and the parts of the anode Ano, the light-emitting functional layer EL and the cathode are formed on the lens unit 1 in a shape-following manner.

Based on the specific structure of the above-mentioned display substrate, the lens unit 1 is arranged in the pixel aperture region K1 and includes the plurality of lenses arranged in an array form. Each lens includes the central lens portion 101 and at least one peripheral lens portion 102 surrounding the central lens portion 101. When each lens is formed in such a manner that the central lens portion 101 is surrounded by the peripheral lens portion 102, the lens is provided with a plurality of recesses, i.e., the quantity of lenses in the lens unit 1 is increased, so it is able to increase a lens filling rate in the pixel aperture region K1, thereby to significantly improve the light extraction efficiency in the pixel aperture region K1. Furthermore, during the arrangement of the lens unit 1 including the above-mentioned lens structure, only the matching between boundaries of the adjacent lenses, rather than the matching between boundaries of the central lens portion 101 and the peripheral lens portion 102 in each lens, needs to be taken into consideration, so it is able to prevent the difficulty in the layout of the lenses from being increased while ensuring the high light extraction efficiency.

In addition, in the embodiments of the present disclosure, the light extraction efficiency is increased through changing the structure of the lens, without any increase in the power consumption of the sub-pixel driving circuitry, so it is able to reduce the overall power consumption of the display substrate.

As shown in FIGS. 1 to 7, in some embodiments of the present disclosure, an orthogonal projection of the central lens portion 101 onto the base substrate has a first boundary J1, an orthogonal projection of the peripheral lens portion 102 onto the base substrate has an outer boundary 102w away from the central lens portion 101, and the outer boundary 102w has a same shape as the first boundary J1.

Illustratively, the orthogonal projection of the central lens portion 101 onto the base substrate includes an axisymmetric pattern, and the orthogonal projection of the peripheral lens portion 102 onto the base substrate includes an axisymmetric pattern.

Illustratively, the orthogonal projection of the peripheral lens portion 102 onto the base substrate has an inner boundary 102n and an outer boundary 102w, and the inner boundary 102n is arranged between the outer boundary 102w and the central lens portion 101. For example, the first boundary J1 of the central lens portion 101 is reused as the inner boundary 102n of the peripheral lens portion 102 adjacent to the central lens portion 101.

Illustratively, the orthogonal projection of the central lens portion 101 onto the base substrate is of a circular or polygonal shape, which will not be particularly defined herein. For example, the orthogonal projection of the central lens portion 101 onto the base substrate is of, but not limited to, a triangular, quadrilateral or regular hexagonal shape.

Illustratively, the first boundary J1 and the outer boundary 102w are each of a regular hexagonal shape, so as to achieve “gap-free filling” in the pixel aperture region K1, thereby to improve the filling rate of the lenses to the greatest extent. Furthermore, the regular hexagonal lenses may be formed more accurately and less distortion may occur, so it is able to improve the luminous efficiency.

In the embodiments of the present disclosure, when the outer boundary 102w has a same shape as the first boundary J1, it is able to achieve the uniformity of the lens, thereby to significantly improve the light extraction efficiency in the pixel aperture region K1.

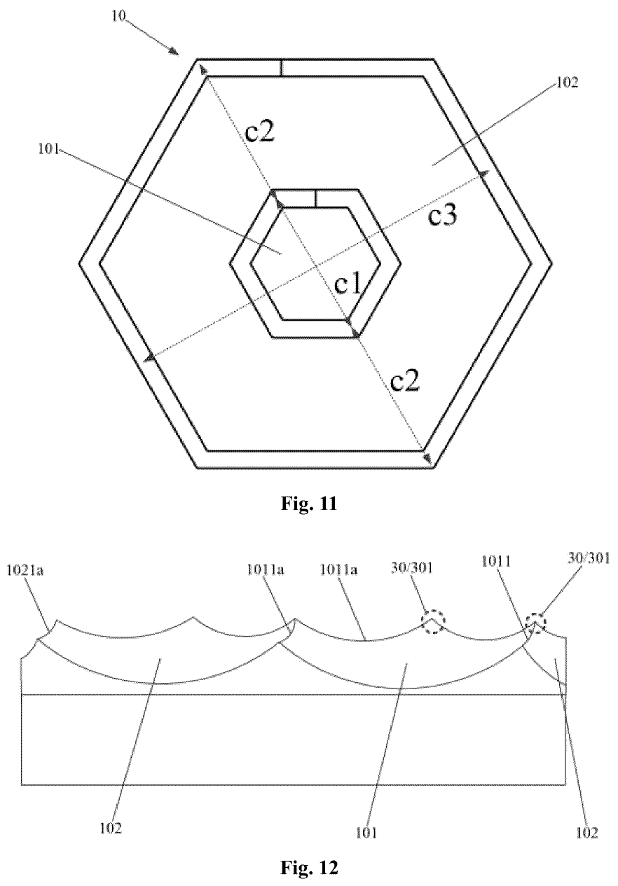

As shown in FIGS. 2 and 11, in some embodiments of the present disclosure, a difference d1 between a width c1 of the central lens portion 101 and a width c2 of the peripheral lens portion 102 in an extension direction of an axis of symmetry of the central lens portion 101 is less than or equal to 0.3 μm.

Illustratively, in the extension direction of the axis of symmetry of the central lens portion 101, the width c1 of the central lens portion 101 is between 4 μm and 4.5 μm, e.g., 4 μm, 4.1 μm, 4.15 μm, 4.2 μm, 4.25 μm, 4.3 μm, 4.37 μm, 4.4 μm, or 4.5 μm.

Illustratively, in the extension of the axis of symmetry of the central lens portion 101, the width c2 of the peripheral lens portion 102 is between 4 μm and 4.5 μm, e.g., 4 μm, 4.1 μm, 4.17 μm, 4.2 μm, 4.25 μm, 4.3 μm, 4.35 μm, 4.4 μm or 4.5 μm.

Illustratively, in the extension direction of the axis of symmetry of the central lens portion 101, an overall width c3 of the peripheral lens portion 102 is between 12 μm and 12.5 μm, e.g., 12 μm, 12.1 μm, 12.15 μm, 12.2 μm, 12.25 μm, 12.3 μm, 12.37 μm, 12.4 μm or 12.5 μm.

Based on the above, the width of the recess of the central lens portion 101 is approximately the same as the width of the recess of the peripheral lens portion 102, so it is able to achieve the uniformity of the lens, thereby to improve the light extraction efficiency of the pixel aperture region K1 in a better manner.

As shown in FIG. 2, and 8 to 10, in some embodiments of the present disclosure, the central lens portion 101 includes a first edge portion 1011, and an orthogonal projection of the first edge portion 1011 onto the base substrate forms the first boundary J1. The peripheral lens portion 102 includes an outer edge portion 1021, and an orthogonal projection of the outer edge portion 1021 onto the base substrate forms the outer boundary 102w. A difference h1 between a height c4 of the first edge portion 1011 and a height c5 of the outer edge portion 1021 in a direction perpendicular to the base substrate is less than or equal to 0.3 μm.

As shown in FIG. 1, in some embodiments of the present disclosure, the central lens portion 101 includes a first edge portion 1011, and an orthogonal projection of the first edge portion 1011 onto the base substrate forms the first boundary J1. The peripheral lens portion 102 includes an outer edge portion 1021, and an orthogonal projection of the outer edge portion 1021 onto the base substrate forms the outer boundary 102w. A difference d2 between a width c6 of the first edge portion 1011 and a width c7 of the outer edge portion 1021 in a direction parallel to the base substrate is less than or equal to 0.3 μm.

Illustratively, the difference d2 between a minimum width of the first edge portion 1011 and a minimum width of the outer edge portion 1021 in the direction parallel to the base substrate is less than or equal to 0.3 μm.

Illustratively, the difference d2 between a maximum width of the first edge portion 1011 and a maximum width of the outer edge portion 1021 in the direction parallel to the base substrate is less than or equal to 0.3 μm.

Illustratively, portions of the first edge portion 1011 and the outer edge portion 1021 having the same height in the direction perpendicular to the base substrate have substantially a same thickness in the direction parallel to the base substrate.

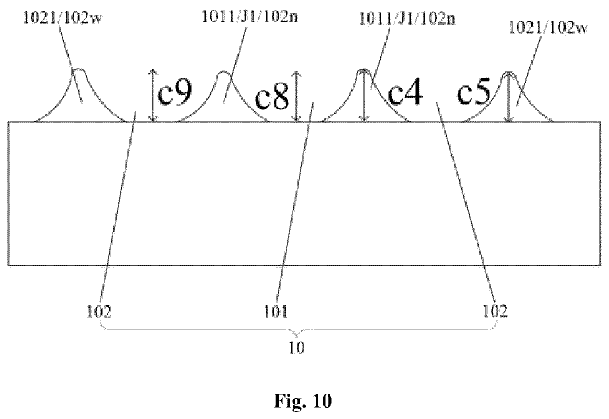

As shown in FIG. 10, in some embodiments of the present disclosure, a difference h2 between a maximum depth c8 of the central lens portion 101 and a maximum depth c9 of the peripheral lens portion 102 in the direction perpendicular to the base substrate is less than or equal to 0.3 μm.

Illustratively, the maximum depth of the central lens portion 101 refers to a maximum depth of the recess of the central lens portion 101, and the maximum depth of the peripheral lens portion 102 refers to a maximum depth of the recess of the peripheral lens portion 102.

In the embodiments of the present disclosure, the lens includes the central lens portion 101 and the peripheral lens portion 102 surrounding the central lens portion 101, the depth of the recess of the central lens portion 101 is approximately the same as the depth of the recess of the peripheral lens portion 102, the first edge portion 1011 of the central lens portion 101 has same morphology (which includes shape and size, e.g., a width in a certain direction) as the outer edge portion 1021, and the maximum width of the recess of the central lens portion 101 is approximately the same as the maximum width of the recess of the peripheral lens portion 102. Based on the above, it is able to achieve the uniformity of the lens, thereby to improve the light extraction efficiency in the pixel aperture region K1 in a better manner.

As shown in FIGS. 1 and 12, in some embodiments of the present disclosure, the central lens portion 101 includes a first edge portion 1011 which includes first edges 1011a and first corners 1011b arranged alternately, each first edge 1011a is coupled to the adjacent first corner 1011b, and a height of the first edge 1011a gradually decreases in a direction away from the first corner 1011b to which the first edge 1011a is coupled.

Illustratively, the first edge portion 1011a and the adjacent first corner 1011b form an integral piece.

Illustratively, an orthogonal projection of the first edge portion 1011 onto the base substrate forms the first boundary J1, and the first boundary J1 is of a regular hexagonal shape. An orthogonal projection of the first edge portion 1011a onto the base substrate forms an edge of a regular hexagon, and an orthogonal projection of the first corner 1011b onto the base substrate forms a corner of the regular hexagon.

Illustratively, a boundary of the first edge 1011a away from the base substrate is an arc bending in a direction away from the base substrate, i.e., a height of the first edge 1011a gradually decreases in a direction away from the first corner 1011b to which the first edge 1011a is coupled.

The light-emitting functional layer EL has a smaller thickness and a larger brightness value in a region with a larger gradient angle, and has a larger thickness and a smaller brightness value in a region with a smaller gradient angle. In this way, it is able to reduce the flatness of the surface of the first edge 1011a away from the base substrate, and increase the brightness value of the portion of the light-emitting functional layer EL covering the first edge 1011a, thereby to increase the overall brightness value of the display substrate.

As shown in FIGS. 1 and 12, in some embodiments of the present disclosure, the peripheral lens portion 102 includes an outer edge portion 1021, the out edge portion 1021 includes outer edge 1021a and outer corner 1021b arranged alternately, each outer edge 1021a is coupled to the adjacent outer corner 1021b, and a height of the outer edge 1021a gradually decreases in a direction away from the outer corners 1021b to which the outer edge 1021a is coupled.

Illustratively, the outer edge 1021a and the adjacent outer corner 1021b form an integral piece.

Illustratively, an orthogonal projection of the outer edge portion 1021 onto the base substrate forms the outer boundary 102w, the outer boundary 102w is of a regular hexagonal shape, an orthogonal projection of the outer edge 1021a onto the base substrate forms an edge of a regular hexagon, and an orthogonal projection of the outer corner 1021b onto the base substrate forms a corner of the regular hexagon.

Illustratively, a boundary of the outer edge 1021a away from the base substrate is an arc bending in a direction away from the base substrate, i.e., a height of the outer edge 1021a gradually decreases in a direction away from the outer corner 1021b to which the outer edge 1021a is coupled.

The light-emitting functional layer EL has a smaller thickness and a larger brightness value in a region with a larger gradient angle, and has a larger thickness and a smaller brightness value in a region with a smaller gradient angle. In this way, it is able to reduce the flatness of the surface of the outer edge 1021a away from the base substrate, and increase the brightness value of the portion of the light-emitting functional layer EL covering the outer edge 1021a, thereby to increase the overall brightness value of the display substrate.

As shown in FIGS. 2 and 12, in some embodiments of the present disclosure, in the lens unit 1, a contact member 30 is formed among adjacent three lenses, and the contact member 30 is provided with a sharp portion 301 at a surface away from the base substrate.

Illustratively, an orthogonal projection of the contact member 30 onto the base substrate is of, but not limited to, a triangular shape.

It should be appreciated that, when the surface of the contact member 30 away from the base substrate is flat, i.e., a flat region is formed, the light-emitting functional layer EL in the flat region does not emit light or emits light with a very low brightness value, so the lens unit 1 should best not be provided with any platform region.

Based on the above, when the contact member 30 is provided with the sharp portion 301 at the surface away from the base substrate, it is able to prevent the formation of the platform region, and provide the portion of the light-emitting functional layer EL covering the contact member 30 with a small thickness, thereby to further increase the brightness value of the light-emitting functional layer EL.

The sharp portion 301 may be formed at the surface of the contact member 30 away from the base substrate through etching. To be specific, after the formation of the lens through etching, an etching process is performed continuously to eliminate the platform region, thereby to form the contact member 30 with the sharp portion 301.

In some embodiments of the present disclosure, the display substrate further includes a pixel definition layer PDL for defining the pixel aperture region K1. In at least a part of the lens units 1, orthogonal projections of a part of the lenses at a periphery of the pixel aperture region K1 onto the base substrate at least partially overlap with an orthogonal projection of the pixel definition layer PDL onto the base substrate.

Illustratively, after the formation of the anode Ano, the pixel definition layer PDL is formed to define a plurality of the pixel aperture regions K1.

Based on the above, in at least a part of the lens units 1, when the orthogonal projections of a part of the lenses at the periphery of the pixel aperture region K1 onto the base substrate at least partially overlap with the orthogonal projection of the pixel definition layer PDL onto the base substrate, the lens array in the lens unit 1 may go beyond the pixel aperture region K1. In this way, it is able to ensure that a lens filling rate in the pixel aperture region K1 is 100%, thereby to improve a light extraction effect of the display substrate.

As shown in FIG. 4, in some embodiments of the present disclosure, the lens includes a first peripheral lens portion 102 that surrounds the central lens portion 101 and a second peripheral lens portion 102 that surrounds the first peripheral lens portion 102.

Illustratively, the lens includes at least two peripheral lens portions 102, one of which surrounds the other.

Illustratively, each peripheral lens portion 102 includes a recess, an inner edge portion arranged at a side of the recess close to the central lens portion 101, and an outer edge portion 1021 arranged at a side of the recess away from the central lens portion 101.

Illustratively, the first edge portion 1011 of the central lens portion 101 is reused as the inner edge portion of the adjacent first peripheral lens portion 102, and the outer edge portion 1021 of the first peripheral lens portion 102 is reused as the inner edge portion of the adjacent second peripheral lens portion 102.

As shown in FIG. 6, for example, in the case that the lens includes a plurality of peripheral lens portions 102 with one surrounding the other, the outer edge portion 1021 of the peripheral lens portion 102 close to the central lens portion 101 is reused as the inner edge portion of the peripheral lens portion 102 away from the central lens portion 101.

Based on the above, when the peripheral lens portions 102 are arranged in such a manner that one surrounds the other, it is able to further improve the light extraction efficiency of the display substrate.

In some embodiments of the present disclosure, the plurality of sub-pixels includes a first color sub-pixel and a second color sub-pixel, a driving current corresponding to the first color sub-pixel is greater than a driving current corresponding to the second color sub-pixel, and a filling rate of the lens unit in the pixel aperture region corresponding to the first color sub-pixel is greater than a filling rate of the lens unit in the pixel aperture region corresponding to the second color sub-pixel.

For example, the plurality of sub-pixels includes a red sub-pixel, a green sub-pixel and a blue sub-pixel, a driving current corresponding to the red sub-pixel is greater than a driving current corresponding to the green sub-pixel, and a driving current corresponding to the green sub-pixel is greater than a driving current corresponding to the blue sub-pixel. A filling rate of the lens unit in the pixel aperture region corresponding to the red sub-pixel is greater than a filling rate of the lens unit in the pixel aperture region corresponding to the green sub-pixel, and a filling rate of the lens unit in the pixel aperture region corresponding to the green sub-pixel is greater than a filling rate of the lens unit in the pixel aperture region corresponding to the blue sub-pixel.

Illustratively, the plurality of sub-pixels further includes a white sub-pixel, a driving current corresponding to the white sub-pixel is less than the driving current corresponding to the blue sub-pixel, and a filling rate of the lens unit in the pixel aperture region corresponding to the white sub-pixel is less than the filling rate of the lens unit in the pixel aperture region corresponding to the blue sub-pixel.

In the embodiments of the present disclosure, different filling rates are set for the sub-pixels with different driving currents, so as to compensate for the brightness values caused by the different driving currents. In this way, when the sub-pixels in different colors are driven through one gamma voltage, it is able to effectively compensate for the brightness values caused by the different driving currents.

In some embodiments of the present disclosure, the plurality of sub-pixels includes a red sub-pixel R, a green sub-pixel G, a blue sub-pixel B, and a white sub-pixel W.

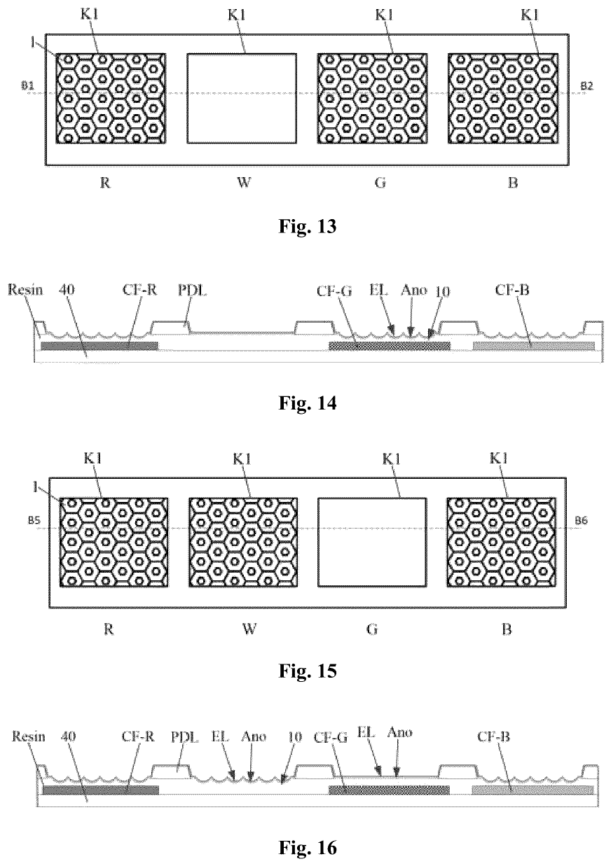

As shown in FIGS. 13 and 14, the pixel aperture region K1 of the white sub-pixel W is not filled with any lens unit 1.

Alternatively, as shown in FIGS. 15 and 16, the pixel aperture region K1 of at least one of the red sub-pixel R, the green sub-pixel G and the blue sub-pixel B is not filled with any lens unit 1.

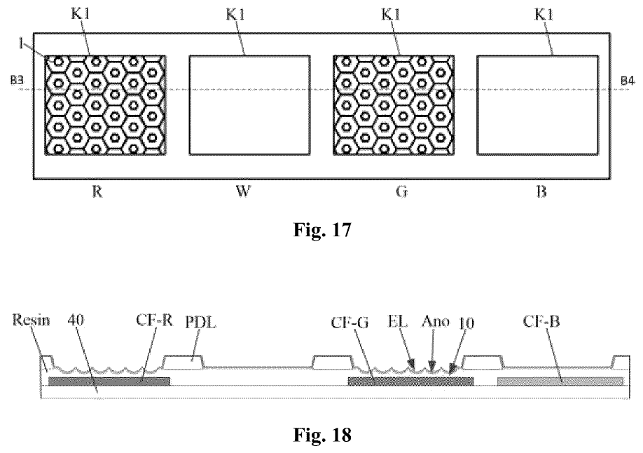

Alternatively, as shown in FIGS. 17 and 18, the pixel aperture region K1 of the white sub-pixel W is not filled with any lens unit 1, and the pixel aperture region K1 of at least one of the red sub-pixel R, the green sub-pixel G and the blue sub-pixel B is not filled with any lens unit 1.

In the embodiments of the present disclosure, the sub-pixels in different colors are provided with different filling rates, so as to compensate for service lives of the sub-pixels. It should be appreciated that, when the sub-pixel is provided with a high filling rate, it is able to prolong the service life of the sub-pixel.

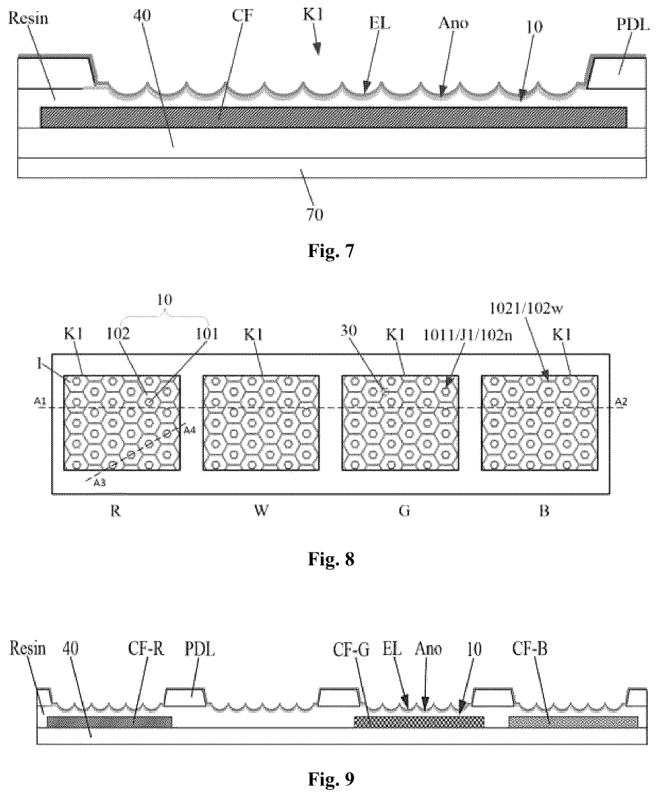

As shown in FIGS. 7 and 13 to 18, in some embodiments of the present disclosure, the display substrate further includes a driving circuitry layer 40 and a color film layer CF. The driving circuitry layer 40 is arranged at a side of the color film layer CF facing the base substrate 70, the color film layer CF is arranged at a side of the lens unit 1 facing the base substrate 70, and an orthogonal projection of the color film layer CF onto the base substrate 70 at least partially overlaps with the orthogonal projection of the pixel aperture region K1 onto the base substrate 70.

Illustratively, the color film layer CF includes a plurality of red color film patterns CF-R, a plurality of green color film patterns CF-G and a plurality of blue color film patterns CF-B, and an orthogonal projection of each color film pattern onto the base substrate at least partially overlaps with the orthogonal projection of pixel aperture regions K1 of the corresponding sub-pixel onto the base substrate.

It should be appreciated that, for each of the red sub-pixel, the green sub-pixel and the blue sub-pixel mentioned hereinabove, the light-emitting functional layer EL directly emits the light in a corresponding color, or the light-emitting functional layer EL emits the white light which passes through the color film pattern in a corresponding color to provide the light in a corresponding color.

Illustratively, the driving circuitry layer 40 includes a plurality of sub-pixel driving circuitries arranged in an array form, and each sub-pixel driving circuitry includes, but not limited to, a 3T1C (i.e., 3 transistors and 1 capacitor) circuitry structure, a 5T1C (i.e., 5 transistors and 1 capacitor) circuitry structure, a 6T1C (i.e., 6 transistors and 1 capacitor) circuitry structure, a 7T1C (i.e., 7 transistors and 1 capacitor) circuitry structure, an 8T1C (i.e., 8 transistors and 1 capacitor) circuitry structure, or a 9T1C (i.e., 9 transistors and 1 capacitor) circuitry structure.

The present disclosure further provides in some embodiments a display apparatus which includes the above-mentioned display substrate.

It should be appreciated that, the display apparatus may be any product or member having a display function, such as television, display, digital photo frame, mobile phone or tablet computer. The display apparatus further includes a flexible circuit board, a printed circuit board and a back plate.

Illustratively, the display apparatus includes, but not limited to, a bottom-emission OLED.

Based on the above-mentioned display substrate, the lens unit 1 is arranged in the pixel aperture region K1 and includes the plurality of lenses arranged in an array form. Each lens includes the central lens portion 101 and at least one peripheral lens portion 102 surrounding the central lens portion 101. When each lens is formed in such a manner that the central lens portion 101 is surrounded by the peripheral lens portion 102, the lens is provided with a plurality of recesses, i.e., the quantity of lenses in the lens unit 1 is increased, so it is able to increase a lens filling rate in the pixel aperture region K1, thereby to significantly improve the light extraction efficiency in the pixel aperture region K1. Furthermore, during the arrangement of the lens unit 1 including the above-mentioned lens structure, only the matching between boundaries of the adjacent lenses, rather than the matching between boundaries of the central lens portion 101 and the peripheral lens portion 102 in each lens, needs to be taken into consideration, so it is able to prevent the difficulty in the layout of the lenses from being increased while ensuring the high light extraction efficiency. In addition, the light extraction efficiency is increased through changing the structure of the lens, without any increase in the power consumption of the sub-pixel driving circuitry, so it is able to reduce the overall power consumption of the display substrate.

When the display apparatus includes the above-mentioned display substrate, it also has the above-mentioned beneficial effects, which will not be particularly defined herein.

The present disclosure further provides in some embodiments a method for manufacturing the above-mentioned display substrate. The display substrate includes a base substrate and a plurality of sub-pixels arranged on the base substrate, and each sub-pixel includes a pixel aperture region K1. The display substrate further includes a plurality of lens units 1, and at least a part of the lens unit 1 is arranged in a corresponding pixel aperture region K1. The method includes forming the lens unit 1. The forming the lens unit 1 specifically includes: forming an organic material layer on the base substrate; forming a photoresist layer at a side of the organic material layer away from the base substrate, and patterning the photoresist layer to form a photoresist pattern; and etching the organic material layer with the photoresist pattern as a mask to form the lens unit 1. The lens unit 1 includes a plurality of lenses 10 arranged in an array form, and each lens includes a central lens portion 101 and at least one peripheral lens portion 102 surrounding the central lens portion 101.

In the display substrate manufactured using the above-mentioned method, the lens unit 1 is arranged in the pixel aperture region K1 and includes the plurality of lenses arranged in an array form. Each lens includes the central lens portion 101 and at least one peripheral lens portion 102 surrounding the central lens portion 101. When each lens is formed in such a manner that the central lens portion 101 is surrounded by the peripheral lens portion 102, the lens is provided with a plurality of recesses, i.e., the quantity of lenses in the lens unit 1 is increased, so it is able to significantly improve the light extraction efficiency in the pixel aperture region K1.

In addition, only the matching between boundaries of the adjacent lenses, rather than the matching between boundaries of the central lens portion 101 and the peripheral lens portion 102 in each lens, needs to be taken into consideration, so it is able to prevent the difficulty in the layout of the lenses from being increased while ensuring the high light extraction efficiency.

In addition, in the embodiments of the present disclosure, the light extraction efficiency is increased through changing the structure of the lens, without any increase in the power consumption of the sub-pixel driving circuitry, so it is able to reduce the overall power consumption of the display substrate.

Furthermore, the lens units in the pixel aperture regions K1 are formed simultaneously, so it is able to ensure the uniformity of the lens units 1.

In some embodiments of the present disclosure, the etching the organic material layer with the photoresist pattern as a mask specifically includes, after the formation of the lens unit 1, forming a contact member 30 among three adjacent lenses in the lens unit 1 through etching, the contact member being provided with a sharp portion 301 at a surface away from the base substrate.

Based on the above, after the formation of the lens, the platform region is etched off to form the contact member 30 having the sharp portion 301.

Based on the above, when the contact member 30 is provided with the sharp portion 301 at the surface away from the base substrate, it is able to prevent the formation of the platform region, and provide the portion of the light-emitting functional layer EL covering the contact 30 with a small thickness, thereby to further increase the brightness value of the light-emitting functional layer EL.

In the embodiments of the present disclosure, the order of the steps is not limited to the serial numbers thereof. For a person skilled in the art, any change in the order of the steps shall also fall within the scope of the present disclosure if without any creative effort.

It should be appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a base substrate, and a plurality of sub-pixels arranged on the base substrate and comprising pixel aperture regions, wherein the display substrate further comprises a plurality of lens units, at least a part of each lens unit is arranged in a corresponding pixel aperture region, each lens unit comprises a plurality of lenses arranged in an array form, each lens comprises a central lens portion and at least one peripheral lens portion, and the peripheral lens portion surrounds the central lens portion.

2. The display substrate according to claim 1, wherein an orthogonal projection of the central lens portion onto the base substrate has a first boundary, and an orthogonal projection of the peripheral lens portion onto the base substrate has an outer boundary arranged away from the central lens portion and having a same shape as the first boundary.

3. The display substrate according to claim 2, wherein a difference d1 between a width of the central lens portion and a width of the peripheral lens portion along an extension direction of an axis of symmetry of the central lens portion is less than or equal to 0.3 μm.

4. The display substrate according to claim 2, wherein the central lens portion comprises a first edge portion, and an orthogonal projection of the first edge portion onto the base substrate forms the first boundary;
the peripheral lens portion comprises an outer edge portion, and an orthogonal projection of the outer edge portion onto the base substrate forms the outer boundary; and
a difference h1 between a height of the first edge portion and a height of the outer edge portion in a direction perpendicular to the base substrate is less than or equal to 0.3 μm.

5. The display substrate according to claim 2, wherein the central lens portion comprises a first edge portion, and an orthogonal projection of the first edge portion onto the base substrate forms the first boundary;
the peripheral lens portion comprises an outer edge portion, and an orthogonal projection of the outer edge portion onto the base substrate forms the outer boundary; and
a difference d2 between a width of the first edge portion and a width of the outer edge portion in a direction parallel to the base substrate is less than or equal to 0.3 μm.

6. The display substrate according to claim 2, wherein a difference h2 between a maximum depth of the central lens portion and a maximum depth of the peripheral lens portion in the direction perpendicular to the base substrate is less than or equal to 0.3 μm.

7. The display substrate according to claim 2, wherein the outer boundary is of a regular hexagonal shape.

8. The display substrate according to claim 1, wherein the central lens portion comprises a first edge portion, the first edge portion comprises first edges and first corners arranged alternately, each first edge is coupled to an adjacent first corner, and a height of the first edge gradually decreases in a direction away from the first corner to which the first edge is coupled.

9. The display substrate according to claim 1, wherein the peripheral lens portion comprises an outer edge portion, the outer edge portion comprises outer edges and outer corners arranged alternately, each outer edge is coupled to an adjacent outer corner, and a height of the outer edge decreases in a direction away from the outer corner to which the outer edge is coupled.

10. The display substrate according to claim 1, wherein in the lens unit, a contact member is formed among three adjacent lenses, and the contact member is provided with a sharp portion at a surface away from the base substrate.

11. The display substrate according to claim 1, further comprising a pixel definition layer for defining the pixel aperture regions, wherein in at least a part of the lens units, orthogonal projections of a part of the lenses at a periphery of the pixel aperture region onto the base substrate at least partially overlap with an orthogonal projection of the pixel definition layer onto the base substrate.

12. The display substrate according to claim 1, wherein the lens comprises a first peripheral lens portion surrounding the central lens portion and a second peripheral lens portion surrounding the first peripheral lens portion.

13. The display substrate according to claim 1, wherein the plurality of sub-pixels comprises a first color sub-pixel and a second color sub-pixel, a driving current corresponding to the first color sub-pixel is greater than a driving current corresponding to the second color sub-pixel, and a filling rate of the lens unit in the pixel aperture region corresponding to the first color sub-pixel is greater than a filling rate of the lens unit in the pixel aperture region corresponding to the second color sub-pixel.

14. The display substrate according to claim 13, wherein the plurality of sub-pixels comprises a red sub-pixel, a green sub-pixel and a blue sub-pixel, a driving current corresponding to the red sub-pixel is greater than a driving current corresponding to the green sub-pixel, and a driving current corresponding to the green sub-pixel is greater than a driving current corresponding to the blue sub-pixel;
a filling rate of the lens unit in the pixel aperture region corresponding to the red sub-pixel is greater than a filling rate of the lens unit in the pixel aperture region corresponding to the green sub-pixel; and
a filling rate of the lens unit in the pixel aperture region corresponding to the green sub-pixel is greater than a filling rate of the lens unit in the pixel aperture region corresponding to the blue sub-pixel.

15. The display substrate according to claim 14, wherein the plurality of sub-pixels further comprises a white sub-pixel, a driving current corresponding to the white sub-pixel is less than the driving current corresponding to the blue sub-pixel, and a filling rate of the lens unit in the pixel aperture region corresponding to the white sub-pixel is less than the filling rate of the lens unit in the pixel aperture region corresponding to the blue sub-pixel.

16. The display substrate according to claim 1, wherein the plurality of sub-pixels comprises a red sub-pixel, a green sub-pixel, a blue sub-pixel and a white sub-pixel,
wherein a pixel aperture region of the white sub-pixel is not filled with the lens unit; or
a pixel aperture region of at least one of the red sub-pixel, the green sub-pixel and the blue sub-pixel is not filled with the lens unit; or
the pixel aperture region of the white sub-pixel is not filled with the lens unit, and the pixel aperture region of at least one of the red sub-pixel, the green sub-pixel and the blue sub-pixel is not filled with the lens unit.

17. The display substrate according to claim 1, further comprising a driving circuitry layer and a color film layer, wherein the driving circuitry layer is arranged at a side of the color film layer facing the base substrate, the color film layer is arranged at a side of the lens unit facing the base substrate, and an orthogonal projection of the color film layer onto the base substrate at least partially overlaps with an orthogonal projection of the pixel aperture region onto the base substrate.

18. A display apparatus comprising the display substrate according to claim 1.

19. A method for manufacturing the display substrate according to claim 1, the display substrate comprising a base substrate and a plurality of sub-pixels arranged on the base substrate, the sub-pixel comprising a pixel aperture region, the display substrate further comprising a plurality of lens units, at least a part of each lens unit being arranged in a corresponding pixel aperture region, the method comprising forming the lens unit,
wherein the forming the lens unit comprises:
forming an organic material layer on the base substrate;
forming a photoresist layer at a side of the organic material layer away from the base substrate, and patterning the photoresist layer to form a photoresist pattern; and
etching the organic material layer with the photoresist pattern as a mask to form the lens unit, the lens unit comprising a plurality of lenses arranged in an array form, and each lens comprising a central lens portion and at least one peripheral lens portion surrounding the central lens portion.

20. The method according to claim 19, wherein the etching the organic material layer with the photoresist pattern as a mask specifically comprises, after the formation of the lens unit, forming a contact member among three adjacent lenses in the lens unit through etching, and the contact member is provided with a sharp portion at a surface away from the base substrate.
